(19) United States
(12) Patent Application Publication
(10) Pub. No.: US 2024/0385515 A1
(43) Pub. Date: Nov. 21, 2024

(54) METHOD OF FORMING PATTERNS

(71) Applicant: SAMSUNG SDI CO., LTD., Yongin-si (KR)

(72) Inventors: Gyeonghun PARK, Suwon-si (KR); Hyungrang MOON, Suwon-si (KR); Si-Kyun PARK, Suwon-si (KR); Taeksoo KWAK, Suwon-si (KR); Myoungsoo SONG, Suwon-si (KR); Donghyung LEE, Suwon-si (KR); Taewon BEOM, Suwon-si (KR); Donghoon SONG, Suwon-si (KR)

(21) Appl. No.: 18/601,843

(22) Filed: Mar. 11, 2024

(30) Foreign Application Priority Data
May 17, 2023 (KR) 10-2023-0063963

(51) Int. Cl. G03F 7/004; G03F 7/16

(52) U.S. Cl. CPC G03F 7/0042; G03F 7/162; G03F 7/168

(57) ABSTRACT

Provided is a method of forming patterns which includes coating a metal- containing resist composition on a substrate to form a resist layer; coating a composition for removing edge beads along edges of the substrate; performing drying and heat-treatment; and exposing and developing to form a resist pattern, wherein after the composition for removing edge beads is coated, a maximum hump height of the resist layer is less than or equal to about 300 nm in an area of about 1 mm to about 30 mm from the edges of the substrate toward a center of the substrate.

### CROSS-REFERENCE TO RELATED APPLICATION

The present application claims priority to and the benefit of Korean Patent Application No. 10-2023-0063963, filed on May 17, 2023, in the Korean Intellectual Property Office, the entire of which is incorporated by reference herein.

### BACKGROUND

### 1. Field

Embodiments of this disclosure relate to a method of forming patterns including coating a composition for removing edge beads in order to reduce metal contamination occurring along wafer edges.

### 2. Description of the Related Art

In recent years, a semiconductor industry has seen by a substantially continuous reduction of critical dimensions, and this dimensional reduction would benefit from new types or kinds of high-performance photoresist materials and a patterning method that satisfy a desire for processing and patterning having increasingly smaller features.

With the recent rapid development of the semiconductor industry, a semiconductor device would benefit from a fast operation speed and large storage capacity, and in line with this requirement, process technology for improving integration, reliability, and a response speed of the semiconductor device is being developed. For example, it would be beneficial to accurately control/implant impurities in working regions of a silicon substrate and to interconnect these regions to form a device and an ultra-high-density integrated circuit, which may be achieved by a photolithographic process. For example, it would be beneficial to integrate the photolithographic process including coating a photoresist on the substrate, selectively exposing it to ultraviolet (UV) (including extreme ultraviolet (EUV)), electron beams, X rays, and/or the like, and then, developing it.

For example, in the process of forming the photoresist layer, the photoresist is coated on the substrate, mainly while rotating the silicon substrate, wherein the photoresist is coated on an edge and rear surface of the substrate, which may cause indentation or pattern defects in the subsequent semiconductor processes such as etching and ion implantation processes. Accordingly, a process of stripping and removing the photoresist coated on the edge and rear surface of the silicon substrate by using a thinner composition, for example, an EBR (edge bead removal) process may be performed. The EBR process utilizes a composition that exhibits excellent solubility for the photoresist and effectively removes beads and the photoresist remaining in the substrate and generates no photoresist residue.

### SUMMARY

An object of the present invention is to provide a pattern forming method that reduces the defect rate when forming fine patterns.

A method of forming patterns according to some example embodiments includes coating a metal-containing photoresist composition on a substrate to form a photoresist layer; coating a composition for removing edge beads along edges of the substrate; performing drying and heat-treatment; and exposing and developing to form a photoresist pattern,

wherein after the composition for removing edge beads is coated, a maximum hump height of the photoresist layer may be less than or equal to about 300 nm in an area of about 1 mm to about 30 mm from the edges of the substrate toward a center of the substrate. The maximum hump height may be about 10 nm to about 300 nm.

A difference between a surface energy of the photoresist layer and a surface tension of the composition for removing edge beads may be about 2 mN/m to about 15 mN/m.

A surface tension of the composition for removing edge beads may be about 25.0 mN/m to about 40.0 mN/m.

The surface tension of the composition for removing edge beads may be about 27.0 mN/m to about 36.0 mN/m.

The composition for removing edge beads may have a viscosity of about 1 to about 10 cPs.

The coating of the composition for removing edge beads may be performed while rotating the substrate at a speed of about 1,000 to about 4,000 rpm.

The metal compound included in the metal-containing photoresist composition may include at least one selected from an organic oxy group-containing tin compound and an organic carbonyloxy group-containing tin compound.

The metal compound included in the metal-containing photoresist composition may be represented by Chemical Formula 1 below.

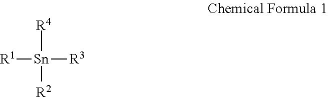

In Chemical Formula 1,

R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 or C30 arylalkyl group, and L^{a}-O—R^{a} (wherein La is a substituted or unsubstituted C1 to C20 alkylene group and R^{a} is a substituted or unsubstituted C1 to C20 alkyl group),

R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 or C30 arylalkyl group, —OR^{b} or —OC(═O)R^{c}, at least one of R² to R⁴ are —OR^{b} or —OC(═O)R^{c},

R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

According to the present invention, it is possible to provide a pattern forming method that reduces the defect rate when forming fine patterns.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic view showing an embodiment of a photoresist coating apparatus.

FIG. 2 is a schematic view of a hump.

FIG. 3 is an electron microscope image of a photoresist thin film according to one example measured after spraying a composition for removing edge beads on a photoresist thin film on a substrate with a profiler equipment.

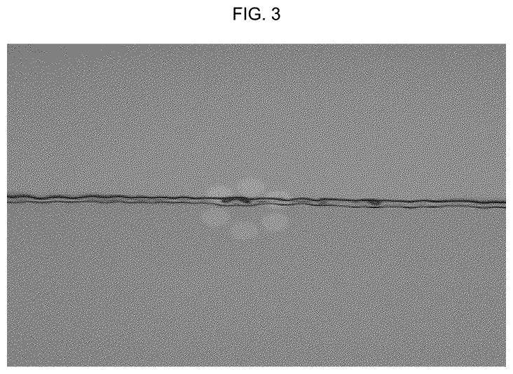

FIG. 4 is an electron microscope image of a photoresist thin film according to a comparative example after spraying a composition for removing edge beads on a photoresist thin film on a substrate with a profiler equipment.

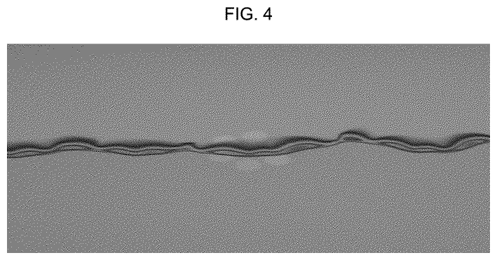

### DETAILED DESCRIPTION

Hereinafter, referring to the drawings, embodiments of the present disclosure are described in more detail. In the following description of the present disclosure, well-known functions or constructions may not be described in order to more clearly describe the subject matter of the present disclosure.

In order to clearly illustrate the subject matter of the present disclosure, certain description and relationships may be omitted, and throughout the disclosure, the same or similar configuration elements are designated by the same reference numerals. Also, because the size and thickness of each configuration shown in the drawing may be arbitrarily shown for better understanding and ease of description, the present disclosure is not necessarily limited thereto.

In the drawings, the thickness of layers, films, panels, regions, etc., may be exaggerated for clarity. In the drawings, the thickness of a part of layers or regions, etc., may be exaggerated for clarity. It will be understood that if an element such as a layer, film, region, or substrate is referred to as being “on” another element, it can be directly on the other element or intervening elements may also be present.

In the present disclosure, “substituted” refers to replacement of a hydrogen atom by deuterium, a halogen group, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” means that a hydrogen atom remains as a hydrogen atom without being replaced by another substituent.

In the present disclosure, the term “alkyl group” means a linear or branched aliphatic hydrocarbon group, unless otherwise defined. The alkyl group may be a “saturated alkyl group” that does not contain any double or triple bonds.

The alkyl group may be a C1 to C20 alkyl group. In some embodiments, the alkyl group may be a C1 to C10 alkyl group or a C1 to C6 alkyl group. For example, a C1 to C5 alkyl group means that the alkyl chain contains 1 to 5 carbon atoms, and may be selected from methyl, ethyl, propyl, iso-propyl, n-butyl, iso-butyl, sec-butyl, and t-butyl.

Examples of the alkyl group include a methyl group, an ethyl group, a propyl group, an isopropyl group, a butyl group, an isobutyl group, a t-butyl group, a pentyl group, a hexyl group, and the like.

In the present disclosure, if a definition is not otherwise provided, the term “cycloalkyl group” refers to a monovalent cyclic aliphatic hydrocarbon group.

The cycloalkyl group may be a cyclopropyl group, a cyclobutyl group, a cyclopentyl group, a cyclohexyl group, and the like.

In the present disclosure, if a definition is not otherwise provided, the term “alkenyl group” is a linear or branched aliphatic hydrocarbon group, and refers to an aliphatic unsaturated alkenyl group containing one or more double bonds.

In the present disclosure, if a definition is not otherwise provided, the term “alkynyl group” is a linear or branched aliphatic hydrocarbon group, and refers to an unsaturated alkynyl group containing one or more triple bonds.

In the present disclosure, “aryl group” means a substituent in which all elements of a cyclic substituent have p-orbitals, and these p-orbitals form a conjugate and may include monocyclic or fused ring polycyclic (e.g., rings that share adjacent pairs of carbon atoms) functional groups.

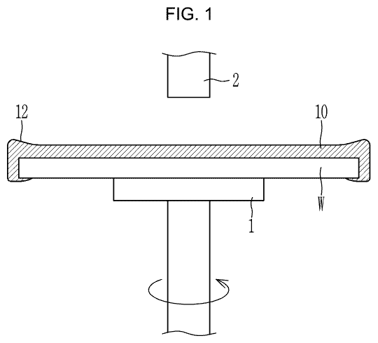

In some embodiments, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted benzophenanthrenyl group, a substituted or unsubstituted triphenylene group, a substituted or unsubstituted perylenyl group, a substituted or unsubstituted fluorenyl group, a substituted or unsubstituted indenyl group, or a combination thereof, but is not limited thereto. FIG. 1 is a schematic view showing an embodiment of a photoresist coating apparatus.

Referring to FIG. 1, a substrate support portion 1 on which a substrate W is placed is equipped therewith, and the substrate support portion 1 includes a spin chuck or a spin coater.

The substrate support portion 1 rotates in a first direction at a set or predetermined rotation speed to provide a centrifugal force to the substrate W. A spray nozzle 2 may be positioned on the substrate support portion 1 but located off the upper portion of the substrate W in the atmospheric region (e.g., the spray nozzle 2 may be spaced apart from the substrate W) so that the spray nozzle may be moved toward the upper portion of the substrate W and spray a metal-containing resist composition 10 during the spraying. Accordingly, the metal-containing resist composition 10 is coated on the surface of the substrate W by the centrifugal force. Herein, the metal-containing resist composition 10 supplied to the center of the substrate W is coated while spreading to the edge of the substrate W by the centrifugal force, wherein a portion of the metal-containing resist composition 10 moves to the side surfaces of the substrate W and the lower surface of the edge of the substrate.

In some embodiments, in the coating process, the metal-containing resist composition 10 is coated mainly in a spin coating method, wherein a set or predetermined amount of the metal-containing resist composition 10 having viscosity (e.g., a set viscosity) is supplied to the center portion of the substrate W and gradually spreads toward the edge of the substrate W by the centrifugal force.

Accordingly, the photoresist film is evenly formed by a rotational speed of the substrate support portion.

In some embodiments, this rotation evaporates a solvent from the solution and thereby gradually increases the viscosity, resulting in making a relatively large amount of the photoresist accumulated on the edge of the substrate by the action of surface tension and severely even onto the lower surface of the edge of the substrate, which is referred to as edge beads 12. As used herein, references to “edge beads” may refer to a single edge bead around a periphery of the substrate.

Hereinafter, a method of forming patterns according to some example embodiments is described.

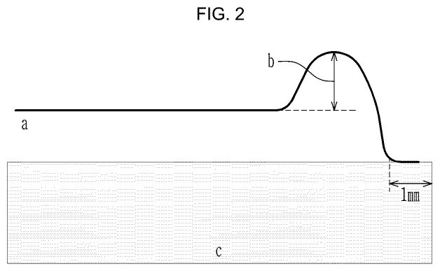

In the present specification, a hump (b) means, as shown in FIG. 2, that a film thickness increases (ΔThickness) at the boundary with a portion where the edge beads are removed.

A method of forming patterns according to another embodiment includes coating a metal-containing photoresist composition on a substrate to form a photoresist layer; coating a composition for removing edge beads along edges (references herein to “edges” may refer to a single edge around a periphery of a substrate) of the substrate; performing drying and heat-treatment; and exposing and developing to form a photoresist pattern,

wherein after the composition for removing edge beads is coated, a maximum hump height of the photoresist layer may be less than or equal to about 300 nm in an area of about 1 mm to about 30 mm from the edges of the substrate toward the center of the substrate.

The maximum hump height may be about 10 nm to about 300 nm.

In some embodiments, the coating of the metal-containing photoresist composition to form the photoresist layer includes coating the metal-containing resist composition on the substrate utilizing a method of spin coating, slit coating, inkjet printing, and/or the like and drying it to form a photoresist film. The metal compound included in the metal-containing photoresist may be for example a tin-based compound, and the tin-based compound may be for example at least one selected from an organic oxy group-containing tin compound and an organic carbonyloxy group-containing tin compound.

For example, the metal compound included in the metal-containing photoresist may be represented by Chemical Formula 1.

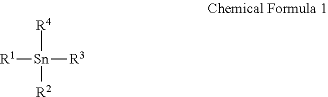

In Chemical Formula 1,

R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 or C30 arylalkyl group, and L^{a}-O—R^{a} (wherein L^{a} is a substituted or unsubstituted C1 to C20 alkylene group and R^{a} is a substituted or unsubstituted C1 to C20 alkyl group),

R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 or C30 arylalkyl group, —OR^{b} or —OC(═O)R^{c}, at least one of R² to R⁴ are —OR^{b} or —OC(═O)R^{c},

R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and

R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

Further, the metal-containing photoresist composition according to one embodiment may include at least one selected from the group consisting of a surfactant, a dispersant, a moisture absorbent, and a coupling agent.

The surfactant may serve to improve coating uniformity and wettability of the photoresist composition. In some example embodiments, the surfactant may be composed of a sulfuric acid ester salt, a sulfonic acid salt, a phosphoric acid ester, a soap, an amine salt, a quaternary ammonium salt, polyethylene glycol, an alkylphenol ethylene oxide adduct, a polyhydric alcohol, a nitrogen-containing vinyl polymer, or a combination thereof, but is not limited thereto. For example, the surfactant may include an alkylbenzenesulfonic acid salt, an alkylpyridinium salt, polyethylene glycol, and/or a quaternary ammonium salt. If the photoresist composition includes the surfactant, the surfactant may be included in an amount of about 0.001 wt % to about 3 wt % based on a total weight of the photoresist composition.

The dispersant may serve to uniformly (e.g., substantially uniformly) disperse each component constituting the photoresist composition in the photoresist composition. In some example embodiments, the dispersant may be composed of an epoxy resin, polyvinyl alcohol, polyvinyl butyral, polyvinylpyrrolidone, glucose, sodium dodecyl sulfate, sodium citrate, oleic acid, linoleic acid, or a combination thereof, but is not limited thereto. If the photoresist composition includes the dispersant, the dispersant may be included in an amount of about 0.001 wt % to about 5 wt % based on a total weight of the photoresist composition.

The moisture absorbent may serve to prevent or reduce adverse effects that would otherwise result from moisture in the photoresist composition. For example, the moisture absorbent may serve to prevent or reduce oxidation of the metal included in the photoresist composition by moisture. In some example embodiments, the moisture absorbent may be composed of polyoxyethylenenonylphenolether, polyethylene glycol, polypropylene glycol, polyacrylamide, or a combination thereof, but is not limited thereto. If the photoresist composition includes the moisture absorbent, the moisture absorbent may be included in an amount of about 0.001 wt % to about 10 wt % based on a total weight of the photoresist composition.

The coupling agent may serve to improve adhesion to the lower film if the photoresist composition is coated on the lower film. In some example embodiments, the coupling agent may include a silane coupling agent. The silane coupling agent may be composed of vinyltrimethoxysilane, vinyltriethoxysilane, vinyltrichlorosilane, vinyltris (β-methoxyethoxy) silane, 3-methacryloxypropyltrimethoxysilane, 3-acryloxypropyl trimethoxysilane, p-styryl trimethoxysilane, 3-methacryloxypropylmethyldimethoxysilane, 3-methacryloxypropylmethyldiethoxysilane, and/or trimethoxy [3-(phenylamino) propyl]silane, but is not limited thereto. If the photoresist composition includes the coupling agent, the coupling agent may be included in an amount of about 0.001 wt % to about 5 wt % based on a total weight of the photoresist composition.

Subsequently, coating a composition for removing edge beads may be performed.

After the edge beads are removed by coating the composition for removing the edge beads, a hump in which a film thickness increase (ΔThickness) occurs may be generated at the boundary with the removed portion.

Because the hump may cause cracks and/or peeling of the film during the baking, contaminate a mask, and generate nonuniformity in the subsequent process, a composition for removing edge beads capable of obtaining a photoresist film having a better edge cut portion after coating the composition for removing edge beads is desirable.

In the coating the composition for removing edge beads according to embodiments of the present disclosure, a difference between a surface energy of the photoresist and a viscosity of the composition for removing edge beads, for example, among main properties, and in the removing the edge beads, process conditions may be adjusted to find a hump height less likely to cause the problems in the subsequent process and thereby, to implement a suitable or optimal method of realizing the corresponding hump height.

The difference between the surface energy of the photoresist layer and the surface tension of the composition for removing edge beads may be about 2 mN/m to about 15 mN/m.

If the difference between the surface energy of the photoresist layer and the surface tension of the composition for removing edge beads is beyond the foregoing range, for example, becomes large, because wettability is lowered, the composition for removing edge beads may hardly dissolve the photoresist and may be expected to exhibit deteriorated cleaning power, and

because there may be mutual pushing pressures due to low affinity on the interface, the hump may be further increased, and the dissolved photoresist may not be removed but remain near the interface in an agglomerated form.

In some embodiments, if the difference between the surface energy of the photoresist layer and the surface tension of the composition for removing edge beads does not reach the foregoing range, for example, becomes smaller, the wettability may be higher, but the composition for removing edge beads may penetrate into the photoresist too quickly, thereby resulting in damage on the photoresist and a swelling phenomenon.

In some embodiments, the method of forming patterns according to the present disclosure may secure a suitable or appropriate difference between the surface energy of the photoresist layer and the surface tension of the composition for removing edge beads, thereby reducing metal-based contamination as well as minimizing or reducing an effect on the photoresist film and thereby, meeting requirements or desirable features of processing and patterning smaller features.

A surface tension of the composition for removing edge beads may be about 25.0 mN/m to about 40.0 mN/m. For example, it may be about 27.0 mN/m to about 40.0 mN/m, or, for example, about 27.0 mN/m to about 36.0 mN/m.

The composition for removing the edge beads may have a viscosity of about 1 to about 10 cPs.

The composition for removing edge beads according to embodiments of the present disclosure may include an additive and a solvent, and the additive and the solvent may be selected within a range that satisfies the above conditions as materials applicable to compositions for removing edge beads in the art.

For example, the additive may be at least one selected from an acid compound such as carboxylic acid, phosphoric acid, phosphorous acid, and sulfuric acid, an alcohol compound, and a ketone compound.

For example, the solvent may be, for example, propylene glycol methyl ether (PGME), propylene glycol methyl ether acetate (PGMEA), propylene glycol butyl ether (PGBE), ethylene glycol methyl ether, diethylglycolethylmethylether, dipropylglycoldimethylether, ethanol, 2-butoxyethanol, n-propanol, isopropanol, n-butanol, isobutanol, hexanol, ethylene glycol, propylene glycol, heptanone, propylene carbonate, butylene carbonate, diethyl ether, dibutyl ether, ethyl acetate, n-butyl acetate (nBA), methyl 3-methoxypropionate, ethyl 3-ethoxypropionate, diisopentyl ether, xylene, acetone, methylethylketone, methylisobutylketone, tetrahydrofuran, dimethylsulfoxide, dimethyl formamide, acetonitrile, diacetone alcohol, 3,3-dimethyl-2-butanone, N-methyl-2-pyrrolidone, dimethyl acetamide, cyclohexanone methyl-2-hydroxy-2-methylpropanate (HBM), gamma butyrolactone (GBL), 1-butanol (n-butanol), ethyllactate (EL), diene butylether (DBE), diisopropylether (DIAE), acetylacetone, butyllactate (n-butylactate), 4-methyl-2-pentenol (or, methyl isobutyl carbinol (MIBC)), 1-methoxy-2-propanol, 1-ethoxy-2-propanol, toluene, xylene, methylethylketone, cyclopentanone, cyclohexanone, 2-hydroxyethyl propionate, 2-hydroxy-2-methylethyl propionate, ethoxyethyl acetate, hydroxyethyl acetate, 2-hydroxy-3-methylbutanoic acidmethyl, 3-methoxymethyl propionate, 3-methoxyethyl propionate, 3-ethoxyethyl propionate, 3-ethoxymethyl propionate, methyl pyruvate, ethyl pyruvate, ethyl acetate, butyl acetate, ethyl lactate, butyl lactate, methyl 2-hydroxyisobutyrate, methoxybenzene, n-butyl acetate, 1-methoxy-2-propyl acetate, methoxyethoxy propionate, ethoxyethoxy propionate, or a mixture thereof, but is not limited thereto.

In some example embodiments, the composition for removing edge beads from metal containing photoresists may include about 0.01 to about 50 wt % of the aforementioned additive and about 50 to about 99.99 wt % of a solvent.

The composition for removing edge beads may further include other additives to be described herein below. In embodiments that include other additives, the solvent may be included in a balance amount excluding the included components.

It may further include at least one other additive selected from a surfactant, a dispersant, a moisture absorbent, and a coupling agent.

The composition for removing the edge beads may be coated while spinning the substrate at a speed of, for example, about 1,000 rpm to about 4,000 rpm.

In some embodiments of the present disclosure, the coating of the composition for removing edge beads may be several times repetitively performed to reduce the metal-based contamination coated on the edge and rear surface of the substrate and also, reduce the photoresist to a suitable or desired level.

The method of forming patterns including the edge bead removal according to the present disclosure may be particularly effective for removing the metal-containing photoresists and, for example, removing undesirable metal residues, for example, tin-based metal residues.

Subsequently, a first heat treatment process of heating the substrate on which the photoresist layer is formed is performed. The first heat treatment process may be performed at a temperature of about 80° C. to about 160° C. and in this process, the solvent is evaporated and the photoresist layer may be more firmly adhered to the substrate to form a photoresist film.

Then, an exposure process of selectively exposing the photoresist film may be performed.

Examples of light used in the exposure process may not only include light having a short wavelength such as an i-line (wavelength: 365 nm), a KrF excimer laser (wavelength: 248 nm), an ArF excimer laser (wavelength: 193 nm), and/or the like, but also light having a high energy wavelength such as EUV (Extreme Ultra Violet; wavelength: 13.5 nm), E-Beam (electron beam), and/or the like.

In some embodiments, the light for the exposure according to some example embodiments may be light having a short wavelength in a range from about 5 nm to about 150 nm but also light having a high energy wavelength such as EUV (Extreme UltraViolet; wavelength: about 13.5 nm), E-Beam (electron beam), and/or the like.

In the forming the photoresist pattern, a negative-type pattern may be formed.

The exposed region of the photoresist film has different solubility from that the unexposed region of the photoresist film, as a polymer is formed by a cross-linking reaction such as condensation between organometallic compounds.

Subsequently, the substrate may be secondarily heat-treated. The second heat treatment process may be performed at about 90° C. to about 200° C. By performing the second heat treatment process, the exposed region of the photoresist film becomes difficult to be dissolved in a developer.

Then, the developing with a developer composition may be performed.

In some embodiments, the photoresist film corresponding to the unexposed region is dissolved and removed by using the developer composition to complete a photoresist pattern corresponding to the negative tone image.

The developer composition used in the method of forming patterns may be, for example, an organic solvent, for example, ketones such as methylethylketone, acetone, cyclohexanone, 2-heptone, and/or the like, alcohols such as 4-methyl-2-propanol, 1-butanol, isopropanol, 1-propanol, methanol, propylene glycol methyl ether (PGME), methyl isobutyl carbinol (MIBC), and/or the like, esters such as propylene glycol methyl ether acetate, ethyl acetate, ethyl lactate, n-butyl acetate, methyl-2-hydroxy isobutyrate, butyrolactone, and/or the like, aromatic compounds such as benzene, xylene, toluene, and/or the like, or a combination thereof.

As described above, the photoresist pattern formed through the exposure by light having high energy such as EUV (Extreme Ultra Violet; wavelength: about 13.5 nm), E-Beam (electron beam), and/or the like as well as light having a wavelength such as i-line (wavelength: about 365 nm), KrF excimer laser (wavelength: about 248 nm), ArF excimer laser (wavelength: about 193 nm), and/or the like may have a width in a range from about 5 nm to about 100 nm. For example, the photoresist pattern may have a width in a range from about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In some embodiments, the photoresist pattern may have a half-pitch with a line width roughness of less than or equal to about 50 nm, for example, less than or equal to about 40 nm, for example, less than or equal to about 30 nm, for example, less than or equal to about 20 nm, for example, less than or equal to about 15 nm and a pitch of less than or equal to about 10 nm, less than or equal to about 5 nm, less than or equal to about 3 nm, or less than or equal to about 2 nm.

Hereinafter, embodiments of the present disclosure will be described in more detail through examples relating to the aforementioned method of forming patterns. However, the technical features of the present disclosure are not limited by the following examples.

### Preparation of Organometal-Containing Photoresist Composition

### Preparation Example A

An organometallic compound having a structure of Chemical Formula C was dissolved at a concentration of 1.0 wt % in 4-methyl-2-pentanol and then, filtered through a 0.1 μm PTFE syringe filter, thereby obtaining a photoresist composition.

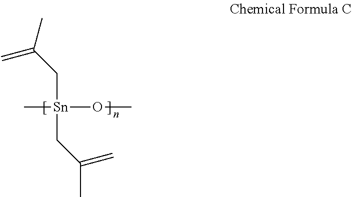

### Preparation Example B

A composition was prepared in substantially the same manner as in Preparation Example A except that an organometallic compound having a structure of Chemical Formula D was used.

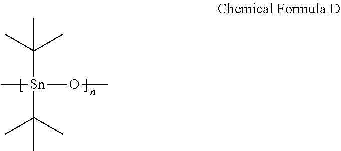

### Preparation of Compositions for Removing Edge Beads

### Preparation Examples 1 to 22

The additives and the solvent according to the composition shown in Table 1 were mixed together, and completely dissolved by shaking at room temperature (25° C.). Thereafter, the compositions for removing the final edge beads were obtained by passing through a filter made of PTFE having a pore size of 0.1 μm.

TABLE 1

| | Compositions for removing edge beads | |
|---|---|---|
| | from metal-containing photoresists | |
| | Additive (wt %) | Solvent (wt %) |
| Preparation Example 1 | 4-nitrocatechol (40) | PGMEA (60) |
| Preparation Example 2 | ethanesulfonic acid (5) | EL (95) |
| Preparation Example 3 | trifluoroacetic acid (30) | GBL (70) |
| Preparation Example 4 | butylphosphinic acid (5) | PGMEA (95) |
| Preparation Example 5 | methanesulfonic acid (30) | MIBC (70) |
| Preparation Example 6 | methylphosphinic acid (5) | PGMEA (95) |
| Preparation Example 7 | propionic acid (40) | GBL (60) |
| Preparation Example 8 | glycolic acid (2) | EL (98) |
| Preparation Example 9 | acetic acid (40) | PGME (60) |
| Preparation Example 10 | catechol (40) | PGMEA (60) |
| Preparation Example 11 | acetonylacetone (27) | nBA (73) |
| Preparation Example 12 | — | nBA (100) |
| Preparation Example 13 | — | MIBC (100) |
| Preparation Example 14 | propionic acid (20) | PGME (80) |
| Preparation Example 15 | tropolone (40) | PGMEA (60) |
| Preparation Example 16 | difluoroacetic acid (0.5) | PGME (95.5) |
| Preparation Example 17 | acetylacetone (10) | EL (90) |
| Preparation Example 18 | vinylphosphonic acid (1) | PGMEA (99) |
| Preparation Example 19 | stearic acid (10) | EL (90) |
| Preparation Example 20 | oleic acid (5) | PGMEA (95) |
| Preparation Example 21 | — | EL (100) |
| Preparation Example 22 | — | PGME (100) |

### Preparation of Developer

### Preparation Example C

A developer was prepared by dissolving 1.0 wt % of acetic acid in PGMEA

### Propylene Glycol Methyl Ether Acetate

### Examples

Onto an 8-inch silicon wafer, 2.0 mL of the organometallic compound-containing photoresist composition according to Preparation Examples A and B was put and then, allowed to stand for 20 seconds and spin-coated at 1500 rpm for 30seconds (PR (A) or PR (B) forming step). Subsequently, as shown in Table 2, 10 mL of each of the compositions for removing edge beads according to the preparation examples was put from 1 mm above the outer periphery of the wafer and then, rotated at a process speed shown in Table 2 for 30 seconds and dried at 160° C. for 60 seconds.

### Evaluation 1: Measurement of Surface Energy of Photoresist Layer

2.0 mL of each of the organometallic compound-containing photoresist compositions according to the preparation examples was put in an 8-inch silicon wafer, allowed to stand for 20 seconds, spin-coated at 1500 rpm for 30 seconds, and heat- treated at 100° C. for 60 seconds, thereby forming a photoresist layer.

After cleaning the surface of the photoresist layer, DSA100 (KR ÜSS GmbH) was mounted on the surface to measure a contact angle of deionized water (DIW), a contact angle of diiodomethane, and surface energy calculated in an OWRK method. The same measurement was 5 times repeated to obtain an average value of the other 3 measurements excluding the upper and lower limits, and the results are shown in Table 2.

### Evaluation 2: Measurement of Surface Tension of Compositions for Removing Edge Beads

Each of the composition for removing edge beads according to Preparation Examples 1 to 22 was 5 times repeatedly measured with respect to surface tension at 25° C. by using a K11-MK1 (KRÜSS GmbH) surface tensiometer, and then, an average value of the other 3 measurements excluding the upper and lower limits was calculated and then, provided in Table 2.

### Evaluation 3: Measurement of Viscosity of Compositions for Removing Edge Beads

Each of the composition for removing edge beads according to Preparation Examples 1 to 22 was 5 times repeatedly measured with respect to absolute viscosity under conditions of 25° C. and Torque % 45 by using LVDV-III-U CP (Brookfield Corp.), and then, an average value of the other 3 measurements excluding the upper and lower limits was calculated and then, provided in Table 2.

### Evaluation 4: Evaluation of Hump

FIG. 2 is a schematic view of a hump.

Referring to FIG. 2, hump means ΔThickness (Hump) generated by convex ends of a photoresist thin film containing an organic metal compound after spraying the compositions for removing edge beads from metal-containing photoresists, and ΔThickness (Hump) values measured with Tencor's Profiler P17OF facility are shown in Table 2.

The measured hump heights were evaluated according to the following criteria, and the results were also described.

A: hump height≤100 nm

B: 100 nm<hump height≤300 nm

C: 300 nm<hump height≤1,000 nm

D: 1000 nm<hump height

### Evaluation 5: Evaluation of Defective Rate of Edge Pattern

Each of the wafers of the examples, from which the edge bead removal was completed, was exposed into a 1 cm×1 cm square pattern with a dose of 40 mJ by using an ArF scanner (XT1250D, ASML), cured at 170° C. for 60 seconds, developed with a developer composition (Preparation Example C) on a spin at 1500 rpm for 30 seconds, and then, cured at 240° C. for 60 seconds.

If the curing was completed, the pattern wafer on which a line/space CD pattern was formed was transported to a CD-SEM measuring equipment to measure a CD (critical dimension) size. The CD size was determined by performing a measurement at 12 points on the CD-SEM image and calculating an average value thereof, and a defect rate was calculated according to Equation 1 by setting 80 nm as a target CD and counting points where present beyond an error range (+10%) from the target CD or where bridges or scums occurred, wherein the defective rate of 1.5% or less was evaluated as good, but the defective rate of greater than 1.5% was evaluated as defective, and then, the results are shown in Table 2.

$$Defective rate of edge pattern = ( Number of defective shots / Number of total shots ) * 100 \qquad Equation 1$$

TABLE 2

| | | | Composition | | | | | | | |
|---|---|---|---|---|---|---|---|---|---|---|
| | | | for removing | | | | | Hump | | |
| | Photoresist layer | | edge beads | | Surface | | | characteristics | | |
| | | Surface | | Surface | energy | | Process | Hump | | Pattern |
| | Preparation | energy | Preparation | tension | difference | Viscosity | speed | height | | defective |
| | Example | (mN/m) | Example | (mN/m) | (mN/m) | (cPs) | (rpm) | (nm) | Evaluation | rate |
| Example 1 | PR A | 41.9 | Preparation | 27.9 | 14.0 | 9.43 | 2000 | 235 | B | Good |
| | | | Example 1 | | | | | | | |
| Example 2 | | | Preparation | 31.3 | 10.6 | 2.75 | 2000 | 146 | B | Good |
| | | | Example 2 | | | | | | | |
| Example 3 | | | Preparation | 35.3 | 6.6 | 1.47 | 1000 | 157 | B | Good |
| | | | Example 3 | | | | | | | |
| Example 4 | | | Preparation | 27.6 | 14.3 | 1.31 | 2000 | 103 | B | Good |
| | | | Example 4 | | | | | | | |
| Example 5 | | | Preparation | 32.6 | 9.3 | 6.44 | 1000 | 132 | B | Good |
| | | | Example 5 | | | | | | | |
| Example 6 | | | Preparation | 27.8 | 14.1 | 1.17 | 3000 | 98 | A | Good |
| | | | Example 6 | | | | | | | |
| Example 7 | | | Preparation | 37.2 | 4.7 | 1.43 | 3000 | 85 | A | Good |
| | | | Example 7 | | | | | | | |
| Example 8 | | | Preparation | 30.3 | 11.6 | 2.83 | 4000 | 59 | A | Good |
| | | | Example 8 | | | | | | | |
| Example 9 | | | Preparation | 28.1 | 13.8 | 1.65 | 2000 | 281 | B | Good |
| | | | Example 9 | | | | | | | |
| Comparative | | | Preparation | 30.3 | 11.6 | 2.83 | 5000 | 477 | C | Defective |
| Example 1 | | | Example 8 | | | | | | | |
| Comparative | | | Preparation | 28.1 | 13.8 | 1.65 | 500 | 1214 | D | Defective |
| Example 2 | | | Example 9 | | | | | | | |
| Comparative | | | Preparation | 29.1 | 12.8 | 25.2 | 2000 | 760 | C | Defective |
| Example 3 | | | Example 10 | | | | | | | |
| Comparative | | | Preparation | 26.9 | 15.0 | 0.92 | 2000 | 474 | C | Defective |
| Example 4 | | | Example 11 | | | | | | | |
| Comparative | | | Preparation | 26.9 | 15.0 | 0.92 | 500 | 1814 | D | Defective |
| Example 5 | | | Example 11 | | | | | | | |
| Comparative | | | Preparation | 25.3 | 16.6 | 1.74 | 2000 | 1624 | D | Defective |
| Example 6 | | | Example 12 | | | | | | | |
| Comparative | | | Preparation | 23.0 | 18.9 | 5.21 | 2000 | 955 | C | Defective |
| Example 7 | | | Example 13 | | | | | | | |
| Example 10 | PR (B) | 35.0 | Preparation | 27.4 | 7.6 | 1.56 | 1000 | 91 | A | Good |
| | | | Example 14 | | | | | | | |
| Example 11 | | | Preparation | 29.1 | 5.9 | 3.55 | 2000 | 89 | A | Good |
| | | | Example 15 | | | | | | | |
| Example 12 | | | Preparation | 32.6 | 2.4 | 7.36 | 2000 | 88 | A | Good |
| | | | Example 5 | | | | | | | |
| Example 13 | | | Preparation | 27.7 | 7.3 | 1.79 | 1000 | 63 | A | Good |
| | | | Example 16 | | | | | | | |
| Example 14 | | | Preparation | 30.1 | 4.9 | 2.51 | 2000 | 55 | A | Good |
| | | | Example 17 | | | | | | | |
| Example 15 | | | Preparation | 27.0 | 8.0 | 1.16 | 2000 | 40 | A | Good |
| | | | Example 18 | | | | | | | |
| Example 16 | | | Preparation | 31.9 | 3.1 | 3.22 | 3000 | 26 | A | Good |
| | | | Example 19 | | | | | | | |
| Example 17 | | | Preparation | 28.2 | 6.8 | 1.55 | 4000 | 13 | A | Good |
| | | | Example 20 | | | | | | | |
| Example 18 | | | Preparation | 30.0 | 5.0 | 2.71 | 2000 | 97 | A | Good |
| | | | Example 21 | | | | | | | |
| Comparative | | | Preparation | 30.1 | 4.9 | 2.51 | 500 | 484 | C | Defective |
| Example 8 | | | Example 17 | | | | | | | |
| Comparative | | | Preparation | 28.2 | 6.8 | 1.55 | 500 | 1021 | D | Defective |
| Example 9 | | | Example 20 | | | | | | | |
| Comparative | | | Preparation | 28.2 | 6.8 | 1.55 | 5000 | 329 | C | Defective |
| Example 10 | | | Example 20 | | | | | | | |
| Comparative | | | Preparation | 27.7 | 7.3 | 1.74 | 500 | 924 | C | Defective |
| Example 11 | | | Example 22 | | | | | | | |

Referring to Table 2, the pattern wafers of Examples 1 to 18 exhibited low humps, compared with than Comparative Examples 1 to 11, and thus a low pattern defective rate.

Hereinbefore, the certain embodiments of the present disclosure have been described and illustrated, however, it should be apparent to a person having ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of embodiments of the present disclosure, and the modified embodiments are within the scope of the claims of the present disclosure, and equivalents thereof.

### Description of Symbols

| | |
|---|---|
| 1: substrate support portion | 2: spray nozzle |
| 10: a metal-containing resist composition | 12: edge bead |
| a: photoresist layer | |
| b: Hump (ΔThickness) | |
| c: substrate | |
| W: substrate | |

What is claimed is:

1. A method of forming patterns, comprising:
coating a metal-containing resist composition on a substrate to form a resist layer;
coating a composition for removing edge beads along edges of the substrate;
performing drying and heat-treatment; and
exposing and developing to form a resist pattern,
wherein after the composition for removing edge beads is coated, a maximum hump height of the resist layer is less than or equal to about 300 nm in an area of about 1 mm to about 30 mm from the edges of the substrate toward a center of the substrate.

2. The method as claimed in claim 1, wherein:
the maximum hump height is about 10 nm to about 300 nm.

3. The method as claimed in claim 1, wherein:
a difference between a surface energy of the resist layer and a surface tension of the composition for removing edge beads is about 2 mN/m to about 15 mN/m.

4. The method as claimed in claim 1, wherein:
a surface tension of the composition for removing edge beads is about 25.0 mN/m to about 40.0 mN/m.

5. The method as claimed in claim 1, wherein:
a surface tension of the composition for removing edge beads is about 27.0 mN/m to about 36.0 mN/m.

6. The method as claimed in claim 1, wherein:
the composition for removing edge beads has a viscosity of about 1 to about 10 cPs.

7. The method as claimed in claim 1, wherein:
the coating of the composition for removing edge beads is performed while rotating the substrate at a speed of about 1,000 to about 4,000 rpm.

8. The method as claimed in claim 1, wherein:
a metal compound included in the metal-containing resist includes at least one selected from an organic oxy group-containing tin compound and an organic carbonyloxy group-containing tin compound.

9. The method as claimed in claim 1, wherein:
a metal compound included in the metal-containing resist is represented by Chemical Formula 1: 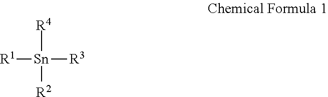
wherein, in Chemical Formula 1,
R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 or C30 arylalkyl group, and L^{a}-O—R^{a} (wherein L^{a} is a substituted or unsubstituted C1 to C20 alkylene group and R^{a} is a substituted or unsubstituted C1 to C20 alkyl group),
R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 or C30 arylalkyl group, —OR^{b} or —OC(═O)R^{c},
at least one of R² to R⁴ are —OR^{b} or —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.
